(19) United States
(12) Patent Application Publication
(10) Pub. No.: US 2025/0212643 A1
(43) Pub. Date: Jun. 26, 2025

(54) DISPLAY PANEL AND DISPLAY DEVICE

(71) Applicant: LG Display Co., Ltd., Seoul (KR)

(72) Inventor: Sungki HONG, Incheon (KR)

(73) Assignee: LG Display Co., Ltd., Seoul (KR)

(21) Appl. No.: 18/898,344

(22) Filed: Sep. 26, 2024

(30) Foreign Application Priority Data
Dec. 20, 2023 (KR) 10-2023-0187236

(51) Int. Cl. H10K 59/35; G06F 3/041; G06V 40/13; H10K 59/122; H10K 59/40

(52) U.S. Cl. CPC H10K 59/353; G06F 3/0412; G06V 40/1318; H10K 59/122; H10K 59/40

(57) ABSTRACT

A display panel includes a first area having a plurality of first pixel areas and a plurality of transmissive areas. A light emitting element is disposed in each first pixel area and each transmissive area overlaps an opening of a cathode electrode of the light emitting element. The display panel further includes a second area having a plurality of second pixel areas and having a higher pixel density than the first area, a touch sensor disposed in the first area and the second area and including a touch sensor metal and a bridge metal located in different layers, a first touch interlayer insulating film disposed between the touch sensor metal and the bridge metal in the first area and the second area, and a second touch interlayer insulating film disposed on the first touch interlayer insulating film in the plurality of transmissive areas of the first and second areas.

### CROSS-REFERENCE TO RELATED APPLICATION

This application claims priority to Korean Patent Application No. 10-2023-0187236 filed on Dec. 20, 2023 in the Korean Intellectual Property Office, the entire contents of which are hereby expressly incorporated by reference into the present application.

### BACKGROUND

### Technical Field

The present disclosure relates to a display panel and a display device including the same.

### Discussion of the Related Art

Specific examples of a flat display device include a liquid crystal display device, an organic light emitting display device, an inorganic light emitting display device, a quantum dot display device, and the like.

In addition to an image display function, such display device can provide a photographing function, a biometric recognition function, and the like. To this end, the display device can be equipped with elements such as a camera and a detection sensor.

These elements such as the camera and the detection sensor can be disposed in a bezel area of the display panel, in a notch area at an end (e.g., an upper end) of a screen of the display panel, or in a punch hole within the screen.

Recently, to further enlarge the screen or a display area of the display panel, a technology of defining an area with a low pixel density or low resolution in the screen or a display area of the display panel and placing an infrared sensor or an infrared camera under such area to recognize a face is being proposed.

In addition, a technology of placing a fingerprint sensor under a partial area of a high-resolution area (an area with a higher pixel density than the low-resolution area) of the display panel to recognize a fingerprint is also being proposed.

The description provided in the background section should not be assumed to be prior art merely because it is mentioned in or associated with the background section. The background section can include information that describes one or more aspects of the subject technology.

### SUMMARY OF THE DISCLOSURE

For accurate facial recognition, a transmittance of infrared light (e.g., 940 nm wavelength) can be increased in a transmissive area of a low-resolution area of a display panel. To this end, sub-pixels and signal lines are not disposed in the transmissive area of the low-resolution area. In particular, a cathode electrode of a light emitting element, which is generally formed throughout a display area, is also removed from the transmissive area of the low-resolution area.

Due to such structure of the low-resolution area, when the display panel is exposed to sunlight for a long period of time or when evaluating UV (ultraviolet) reliability assuming such situation, ultraviolet light introduced via the transmissive area of the low-resolution area can cause outgassing from organic films under the cathode electrode.

In this case, such outgassing can cause reliability problems such as shrinkage of the pixels and a color difference or a luminance decrease of the display panel.

Accordingly, the inventor of the present disclosure has developed a display panel that can reduce a transmittance of ultraviolet light in the transmissive area of the low-resolution area and a method for manufacturing the same, in order to reduce, minimize or solve such reliability problem.

The present disclosure is to provide a display panel that can reduce the transmittance of ultraviolet light in the transmissive area of the low-resolution area, and a display device including the same.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

A display panel according to an example embodiment of the present disclosure includes a first area including a plurality of first pixel areas and a plurality of transmissive areas, wherein a light emitting element is disposed in each first pixel area and each transmissive area overlaps an opening of a cathode electrode of the light emitting element, a second area including a plurality of second pixel areas and having a higher pixel density than the first area, a touch sensor disposed in the first area and the second area and including a touch sensor metal and a bridge metal located in different layers, a first touch interlayer insulating film disposed between the touch sensor metal and the bridge metal in the first area and the second area, and a second touch interlayer insulating film disposed on the first touch interlayer insulating film in the plurality of transmissive areas of the first area and the second area.

A display device according to an example embodiment of the present disclosure includes a display panel including a display area and a non-display area, wherein the display area includes a first area including a plurality of first pixel areas and a plurality of transmissive areas, and a second area including a plurality of second pixel areas and having a higher pixel density than the first area, wherein a light emitting element is disposed in each first pixel area, wherein each transmissive area overlaps an opening of a cathode electrode of the light emitting element, an infrared sensor overlapping the first area and located on a rear surface of the display panel, and a fingerprint sensor overlapping the second area and located on the rear surface of the display panel, and the display panel includes a touch sensor disposed in the first area and the second area and including a touch sensor metal and a bridge metal located in different layers, a first touch interlayer insulating film disposed between the touch sensor metal and the bridge metal in the first area and the second area, and a second touch interlayer insulating film disposed on the first touch interlayer insulating film in the plurality of transmissive areas of the first area and the second area.

Specific details of other example embodiments of the present disclosure are included in the detailed description and drawings.

According to the example embodiments of the present disclosure, while securing the high transmittance of infrared light (e.g., 940 nm wavelength) in the transmissive area of the low-resolution area for the accurate facial recognition, the transmittance of ultraviolet light can be reduced in the transmissive area of the low-resolution area. Accordingly, the reliability of the display panel can be improved even when the display panel is exposed to sunlight for a long time.

According to the example embodiments of the present disclosure, while securing the high transmittance of infrared light of the first wavelength (e.g., 940 nm wavelength) in the transmissive area of the low-resolution area for the accurate facial recognition, the transmittance of infrared light of the second wavelength (e.g., 1300 nm wavelength), which is longer than the first wavelength, can be improved in the fingerprint recognition area. Accordingly, in addition to the accurate facial recognition, a fingerprint recognition rate can be increased and the fingerprint recognition error can be prevented.

Effects of the present disclosure are not limited to the above-mentioned effects, and other effects as not mentioned will be clearly understood by those skilled in the art from following descriptions.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view showing a display device according to an example embodiment of the present disclosure.

FIG. 2 is a plan view showing a low-resolution area of a display device according to an example embodiment of the present disclosure.

FIG. 3 is a cross-sectional view taken along a line III-III in FIG. 2.

FIG. 4 is a plan view showing a fingerprint recognition area of a display device according to an example embodiment of the present disclosure.

FIG. 5 is a cross-sectional view taken along a line V-V in FIG. 4.

FIG. 6 is a plan view showing a normal area of a display device according to an example embodiment of the present disclosure.

FIGS. 7A to 7F are cross-sectional views showing a method for manufacturing a display device according to an example embodiment of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure, and a method of achieving the advantages and features will become apparent with reference to embodiments described later in detail together with the accompanying drawings. However, the present disclosure is not limited to the embodiments as disclosed under, but can be implemented in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” or “over” a second element or layer, the first element or layer can be disposed directly on or over the second element or layer, or can be disposed indirectly on or over the second element or layer with a third element or layer being disposed between the first and second elements or layers.

It will be understood that when an element or layer is referred to as being “connected to”, or “connected to” another element or layer, it can be directly on, connected to, or connected to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top of” or “over” another layer, film, region, plate, or the like, then the former can directly contact the latter or still one or more other layers, films, regions, plates, or the like are disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like can be disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

The terms, such as “below,” “lower,” “above,” “upper” and the like, can be used herein to describe a relationship between element(s) as illustrated in the drawings. It will be understood that the terms are spatially relative and based on the orientation depicted in the drawings.

In descriptions of temporal relationships, for example, temporal precedent relationships between two events such as “after”, “subsequent to”, “before”, etc., another event can occur therebetween unless “directly after”, “directly subsequent” or “directly before” is indicated.

When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, “A,” “B,” “(a),” and “(b),” and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define order or sequence. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, and the like should not be construed such that any aspect or design as described is superior to or advantageous over other aspects or designs. In addition, the term “can” fully encompass all the meanings and coverages of the term “may.” Also, the terms such as “on,” “above,” and “over” are interchangeable.

Further, the term “or” means “inclusive or” rather than “exclusive or”. For example, unless otherwise stated or clear from the context, the expression that “x uses a or b” means any one of natural inclusive permutations.

The terms used in the description below have been selected as being general and universal in the related technical field. However, there can be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term can be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Description.

Hereinafter, a display device according to various embodiments of the present disclosure will be described in detail with reference to the attached drawings. All the components of each display device and panel according all embodiments of the present disclosure are operatively coupled and configured.

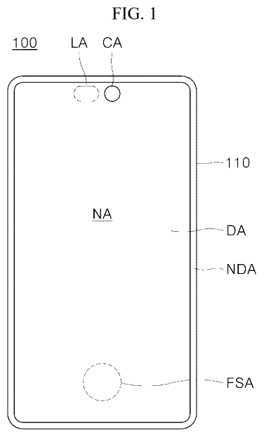

FIG. 1 is a plan view showing a display device according to an example embodiment of the present disclosure.

Referring to FIG. 1, a display device 100 according to example embodiments of the present disclosure can include a display panel 110 that displays an image.

The display panel 110 can include a display area DA (or active area) where a plurality of pixels are arranged to display the image and a non-display area NDA (or non-active area) where the image is not displayed.

Each pixel in the display area DA includes sub-pixels of different colors to render colors of the image. Each sub-pixel can include a light emitting element and a sub-pixel circuit that operates the light emitting element.

The non-display area NDA can be an adjacent area of the display area DA, or a surrounding area of the display area DA. Various signal lines can be disposed in the non-display area NDA and various driving circuits can be connected to or disposed in the non-display area NDA. As an example, the non-display area NDA can be bent so as at least partially not to be visible from the front, can be at least partially obscured by a casing. Embodiments are not limited thereto. As an example, the non-display area NDA can be not bent or not obscured by the casing. The non-display area NDA is also referred to as a bezel or a bezel area.

The display area DA can include a normal area NA, a fingerprint recognition area FSA, and a low-resolution area LA, without being limited thereto. As an example, the fingerprint recognition area FSA and/or the low-resolution area LA can be omitted. The low-resolution area LA can be a first area, the fingerprint recognition area FSA can be a second area, and the normal area NA can be a third area. The display area DA can also include a camera hole CA extending through the display panel 110, without being limited thereto. Alternatively, in one example embodiment, the display area DA can include a camera area that is the same as or similar to the low-resolution area LA instead of the camera hole CA.

The normal area NA and the fingerprint recognition area FSA of the display area DA can have the same pixel density or resolution, without being limited thereto. As an example, the normal area NA and the fingerprint recognition area FSA of the display area DA can have different pixel densities or resolutions. As an example, the normal area NA can have higher or lower pixel density or resolution than the fingerprint recognition area FSA.

The low-resolution area LA of the display area DA can have a lower pixel density or a lower resolution than the normal area NA or the fingerprint recognition area FSA. The pixel density can be interpreted as PPI (Pixels Per Inch), which represents the number of pixels per unit area.

As an example, the low-resolution area LA of the display area DA can include a plurality of transmissive areas arranged between the plurality of sub-pixels, without being limited thereto. As an example, each transmissive area may not include the sub-pixels and signal lines. Therefore, the low-resolution area LA of the display area DA can have the lower pixel density than the normal area NA and/or the fingerprint recognition area FSA.

As an example, the normal area NA and the fingerprint recognition area FSA of the display area DA can have the higher pixel densities than the low-resolution area LA of the display area DA. The normal area NA and the fingerprint recognition area FSA of the display area DA can be high-resolution areas.

The size of the plurality of sub-pixels in the low-resolution area LA can be larger than the sizes of the plurality of sub-pixels in the normal area NA and the fingerprint recognition area FSA. The shape of the plurality of sub-pixels in the low-resolution area LA can be different from the shapes of the plurality of sub-pixels in the normal area NA and the fingerprint recognition area FSA.

The display device 100 can include a touch sensor disposed within the display panel 110. The touch sensor can be disposed in the display area DA. The touch sensor can be configured as a mesh type. A mesh-type touch sensor can include a plurality of openings, and each opening can be positioned to correspond to a light-emitting area of a sub-pixel. The size of each opening can be larger than the size of the light emitting area of the sub-pixel. The size of the plurality of openings of the touch sensor disposed in the low-resolution area LA can be larger than the size of the plurality of openings of the touch sensor disposed in the general area NA and the fingerprint recognition area FSA.

The display device 100 can include a plurality of elements (e.g., optical element) disposed under a rear surface of the display panel 110.

An image sensor (or a camera) that captures the image in a direction of a front surface of the display panel 110 can be disposed under the camera hole CA of the display panel 110. The image sensor (or the camera) can be disposed to overlap the camera hole CA of the display panel 110. The image sensor (or the camera) receives light (e.g., visible light or invisible light) that has passed through the camera hole CA of the display panel 110.

As an example, an infrared sensor (or an infrared camera), for example, for facial recognition can be disposed under the low-resolution area LA of the display panel 110, without being limited thereto. The infrared sensor (or the infrared camera) can be disposed to overlap the low-resolution area LA of the display panel 110. The infrared sensor (or the infrared camera) receives light (e.g., infrared light) that has passed through the low-resolution area LA, particularly the plurality of transmissive areas, of the display panel 110.

A fingerprint sensor can be disposed under the fingerprint recognition area FSA of the display panel 110. The fingerprint sensor can be disposed to overlap the fingerprint recognition area FSA of the display panel 110. The fingerprint sensor receives light (e.g., infrared light) that has passed through the fingerprint recognition area FSA of the display panel 110.

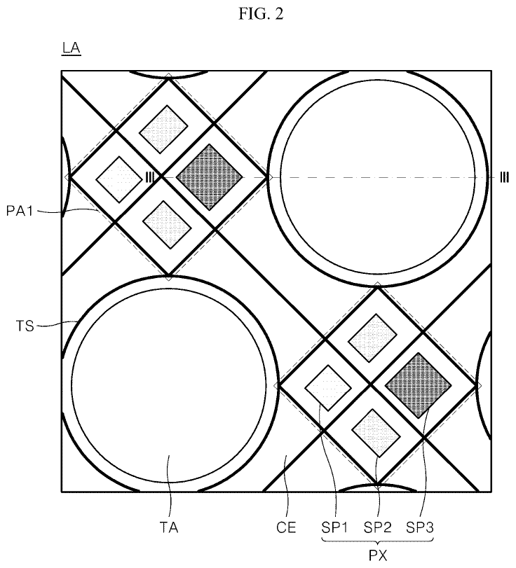

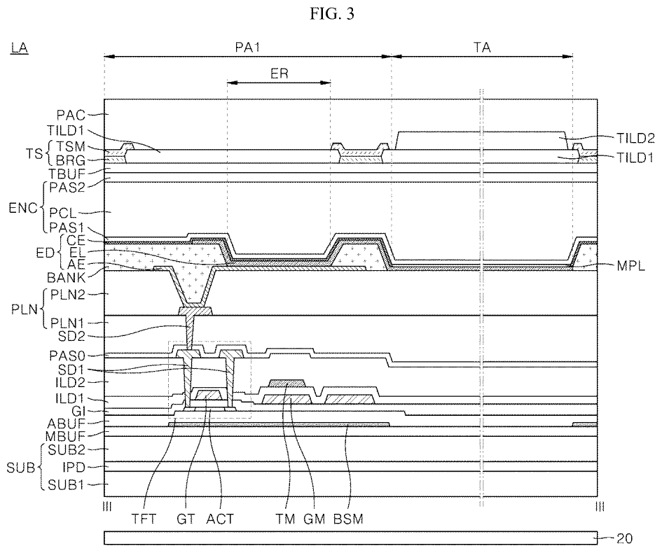

FIG. 2 is a plan view showing the low-resolution area LA of the display device according to an example embodiment of the present disclosure. FIG. 3 is a cross-sectional view taken along a line III-III in FIG. 2. Hereinafter, a description will be made by way of example that one pixel PX is composed of a red sub-pixel SP1, a green sub-pixel SP2, and a blue sub-pixel SP3. However, this is only an example for convenience of description, and the one pixel can be composed of the red sub-pixel, the green sub-pixel, the blue sub-pixel, and a white sub-pixel, or sub-pixels of other colors.

Referring to FIG. 2, the low-resolution area LA of the display panel 110 includes a plurality of first pixel areas PA1 and a plurality of transmissive areas TA.

For example, in the low-resolution area LA, the plurality of first pixel areas PA1 and the plurality of transmissive areas TA can be arranged alternately, without being limited thereto. As an example, the plurality of first pixel areas PA1 and the plurality of transmissive areas TA can be arranged alternately in one or more directions, without being limited thereto. In the low-resolution area LA, the plurality of first pixel areas PA1 and the plurality of transmissive areas TA can be arranged in a 1:1 ratio, without being limited thereto. In contrast, to further increase a light transmittance of the low-resolution area LA, the plurality of first pixel areas PA1 and the plurality of transmissive areas TA can be arranged in a 1:3 ratio. By adjusting a size (or an area) and the number of plurality of transmissive areas TA, the light transmittance of the low-resolution area LA can be adjusted. Embodiments are not limited thereto. As an example, the plurality of first pixel areas PA1 and the plurality of transmissive areas TA can be arranged in a ratio greater than 1:1, a ratio between 1:1 and 1:3 or a ratio smaller than 1:3.

The plurality of sub-pixels can be arranged in each first pixel area PA1. For example, the plurality of sub-pixels can include the red sub-pixel SP1 that emits red light, the green sub-pixel SP2 that emits green light, and the blue sub-pixel SP3 that emits blue light, without being limited thereto. For example, each first pixel area PA1 can include two green sub-pixels SP2 spaced apart from each other. One red sub-pixel SP1, at least one green sub-pixel SP2, and one blue sub-pixel SP3 can constitute one pixel PX. Unlike as shown, one red sub-pixel SP1, one green sub-pixel SP2, one blue sub-pixel SP3, and one white sub-pixel can constitute one pixel PX. The white sub-pixel is a sub-pixel that emits white light. Embodiments are not limited thereto. As an example, each first pixel area PA1 can include one or more red sub-pixel SP1, one or more green sub-pixel SP2, and one or more blue sub-pixel SP3. As an example, one or more white sub-pixel can be further included. As an example, sub-pixels of other colors can be additional or alternatively included.

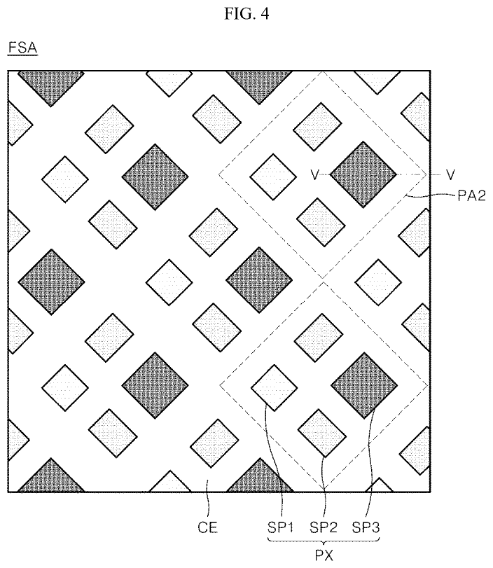

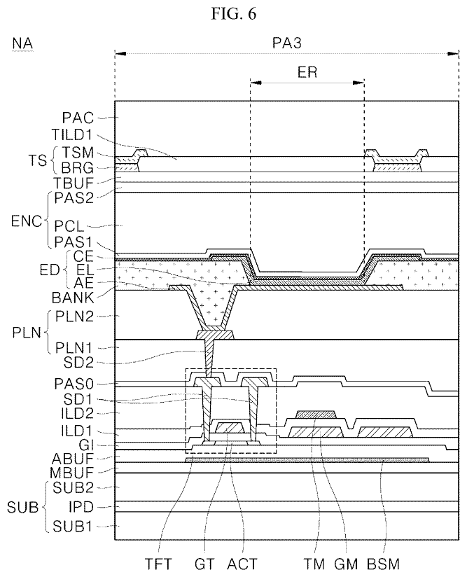

The size of the plurality of first pixel areas PA1 in the low-resolution area LA are larger than the size of the plurality of second pixel areas PA2 (see FIG. 4) in the fingerprint recognition area FSA and the size of the plurality of third pixel areas PA3 (see FIG. 6) in the normal area NA. The size of the plurality of sub-pixels SP1, SP2, SP3 in the low-resolution area LA are larger than the size of the plurality of sub-pixels SP1, SP2, SP3 in the fingerprint recognition area FSA and the size of the plurality of sub-pixels SP1, SP2, SP3 in the normal area NA.

In an area between the first pixel areas PA1, various signal lines including a gate line, a data line, and the like can be disposed.

To increase a light transmittance of the transmissive area TA, the sub-pixels and the signal lines may not be disposed in each transmissive area TA. A cathode electrode CE of a light emitting element ED may not be disposed in each transmissive area TA. As an example, the cathode electrode CE of the light emitting element formed throughout the display area DA may not be formed in the plurality of transmissive areas TA. The plurality of transmissive areas TA can correspond to openings of the cathode electrode CE. The plurality of transmissive areas TA can overlap the openings of the cathode electrode CE, respectively. As an example, the signal lines can be disposed to bypass the plurality of transmissive areas TA.

The mesh-type touch sensor TS disposed in the low-resolution area LA can include a plurality of first openings and a plurality of second openings. Each first opening can be positioned to correspond to the light emitting area of each sub-pixel SP1, SP2, and SP3. The size of each first opening can be larger than the size of the light emitting area of each sub-pixel SP1, SP2, and SP3. The plurality of second openings can be positioned to correspond to the plurality of transmissive areas TA in the low-resolution area LA. The size of the plurality of second openings can be larger than the size of the plurality of transmissive areas TA in the low-resolution area LA.

Referring to FIG. 3, a stacked structure of the first pixel area PA1 included in the low-resolution area LA will be described.

A substrate SUB can include a first substrate SUB1, an interlayer insulating film IPD, and a second substrate SUB2. The interlayer insulating film IPD can be located between the first substrate SUB1 and the second substrate SUB2. By constructing the substrate SUB with the first substrate SUB1, the interlayer insulating film IPD, and the second substrate SUB2, moisture penetration can be reduced or prevented. For example, the first substrate SUB1 and the second substrate SUB2 can be polyimide (PI) substrates, without being limited thereto. As an example, the first substrate SUB1 and the second substrate SUB2 can be made of any other insulating materials such as glass, polycarbonate, polyethylene, etc. For example, the interlayer insulating film IPD can be made of an inorganic material. Embodiments are not limited thereto. As an example, the substrate SUB can include single one substrate without any interlayer insulating film, or can include more than two substrates with or without interlayer insulating films interposed therebetween.

A multi-buffer layer MBUF can be disposed on the second substrate SUB2, and a light blocking layer BSM that blocks light can be disposed on the multi-buffer layer MBUF. For example, the multi-buffer layer MBUF can be formed of a single layer or multiple layers of inorganic materials. For example, the light blocking layer BSM can be formed of a single layer or multi layers of metal materials. As an example, the multi-buffer layer MBUF and/or the light blocking layer BSM can be omitted depending on the design.

An active buffer layer ABUF can be disposed on the light blocking layer BSM. An active layer ACT of a thin film transistor TFT can be disposed on the active buffer layer ABUF. For example, the active buffer layer ABUF can be formed of a single layer or multiple layers of inorganic materials. For example, the active layer ACT can be made of a semiconductor material, without being limited thereto. As an example, the active buffer layer ABUF can be omitted depending on the design.

A gate insulating film GI can be disposed while covering the active layer ACT. For example, the gate insulating film GI can be formed of a single layer or multiple layers of inorganic materials. Although it is shown that the gate insulating film GI is formed throughout the first pixel area PA1 and the transmissive area TA, embodiments are not limited thereto. As an example, the gate insulating film GI can be patterned to cover the active layer ACT of the thin film transistor TFT.

A gate electrode GATE of the thin film transistor TFT can be disposed on the gate insulating film GI. In this regard, a gate material layer GM can be disposed on the gate insulating film GI along with the gate electrode GATE of the thin film transistor TFT at a location different from a formation location of the thin film transistor TFT, without being limited thereto. For example, the gate electrode GATE and the gate material layer GM can be formed of a single layer or multiple layers of conductive materials (e.g., metal materials).

A first interlayer insulating film ILD1 can be disposed while covering the gate electrode GATE and the gate material layer GM. As an example, the first interlayer insulating film ILD1 can be disposed while covering the patterned gate insulating film GI. A metal pattern TM can be disposed on the first interlayer insulating film ILD1. The metal pattern TM can be located at a location different from the formation location of the thin film transistor TFT. A second interlayer insulating film ILD2 can be disposed while covering the metal pattern TM on the first interlayer insulating film ILD1. For example, the first interlayer insulating film ILD1 and the second interlayer insulating film ILD2 can be formed of a single layer or multiple layers of inorganic or organic materials. For example, the metal pattern TM can be formed of a single layer or multiple layers of conductive materials (e.g., metal materials).

Two first source-drain electrode patterns SD1 can be disposed on the second interlayer insulating film ILD2. One of the two first source-drain electrode patterns SD1 can be a source electrode of the thin film transistor TFT and the other can be a drain electrode of the thin film transistor TFT. For example, the first source-drain electrode patterns SD1 can be formed of a single layer or multiple layers of conductive materials (e.g., metal materials).

The two first source-drain electrode patterns SD1 can be electrically connected to one side and the other side of the active layer ACT via contact holes extending through the second interlayer insulating film ILD2, the first interlayer insulating film ILD1, and the gate insulating film GI.

A passivation layer PAS0 is disposed while covering the two first source-drain electrode patterns SD1. For example, the passivation layer PAS0 can be formed of a single layer or multiple layers of inorganic materials.

A planarization layer PLN can be disposed on the passivation layer PAS0. The planarization layer PLN can include a first planarization layer PLN1 and a second planarization layer PLN2. For example, the first planarization layer PLN1 and the second planarization layer PLN2 can be formed of a single layer or multiple layers of organic materials. Embodiments are not limited thereto. As an example, the planarization layer PLN can include single one planarization layer or more than two planarization layers.

The first planarization layer PLN1 can be disposed on the passivation layer PAS0.

A second source-drain electrode pattern SD2 can be disposed on the first planarization layer PLN1. The second source-drain electrode pattern SD2 can be connected to one of the two first source-drain electrode patterns SD1 via the contact hole extending through the first planarization layer PLN1. The second source-drain electrode pattern SD2 can be a connection electrode. For example, the second source-drain electrode pattern SD2 can be formed of a single layer or multiple layers of conductive materials (e.g., metal materials). As an example, the second source-drain electrode pattern SD2 can be omitted depending on the design.

The second planarization layer PLN2 can be disposed while covering the second source-drain electrode pattern SD2. The light emitting element ED can be disposed on the second planarization layer PLN2.

In a stacked structure of the light emitting element ED, an anode electrode AE can be disposed on the second planarization layer PLN2. The anode electrode AE can be electrically connected to the second source-drain electrode pattern SD2 via a contact hole extending through the second planarization layer PLN2. For example, the anode electrode AE can be made of a metal material, a transparent conductive oxide, etc., or a combination thereof. As an example, in the case where the second source-drain electrode pattern SD2 is omitted, the anode electrode AE can be electrically connected to one of the two first source-drain electrode patterns SD1 via a contact hole extending through the planarization layer PLN.

A bank BANK can be disposed while covering a portion of the anode electrode AE. A portion of the bank BANK corresponding to a light emitting area ER of a sub-pixel SP can be removed. For example, the bank BANK can be made of an inorganic or organic material. As an example, the bank BANK can be made of an organic material containing black pigment.

A portion of the anode electrode AE can be exposed by an opening of the bank. A light emitting layer EL can be located at the opening of the bank BANK and on a side surface of the bank BANK. As an example, the light emitting layer EL can be located on a portion of the side surface of the bank BANK, or can be further located on at least a portion of a top surface of the bank BANK, without being limited thereto.

At the opening of the bank BANK, the light emitting layer EL can be in contact with the anode electrode AE. The cathode electrode CE can be disposed on the light emitting layer EL and the bank BANK. For example, the cathode electrode CE can be made of a metal material, a transparent conductive oxide, etc., or a combination thereof.

The light emitting element ED can be formed by the anode electrode AE, the light emitting layer EL, and the cathode electrode CE. The light emitting layer EL can include at least one organic film. As an example, the light emitting layer EL can include a hole injection layer, a hole transport layer, an organic light emitting layer, an electron transport layer, and an electron injection layer. At least one of the hole injection layer, the hole transport layer, the electron transport layer, and the electron injection layer of the light emitting layer EL can be a common layer commonly disposed in a plurality of sub-pixels. For example, a hole injection layer and a hole transport layer of the light emitting layer EL can be commonly disposed in a plurality of sub-pixels. For example, the electron transport layer and the electron injection layer of the light emitting layer EL can be commonly disposed in a plurality of sub-pixels. For example, the hole injection layer, hole transport layer, electron transport layer, and electron injection layer of the light emitting layer EL can be commonly disposed in a plurality of sub-pixels.

An encapsulation layer ENC that can at least reduce, minimize or block penetration of external moisture or oxygen into the light emitting element ED can be disposed on the light emitting element ED.

The encapsulation layer ENC can have a single-layer structure or a multi-layer structure. For example, as shown in FIG. 3, the encapsulation layer ENC can include a first encapsulation layer PAS1, a second encapsulation layer PCL, and a third encapsulation layer PAS2. For example, the first encapsulation layer PAS1 and the third encapsulation layer PAS2 can be inorganic films and the second encapsulation layer PCL can be an organic film, without being limited thereto. Among the first encapsulation layer PAS1, the second encapsulation layer PCL, and the third encapsulation layer PAS2, the second encapsulation layer PCL can be the thickest and can serve as a planarization layer, without being limited thereto.

The first encapsulation layer PAS1 can be disposed on the cathode electrode CE and can be disposed closest to the light emitting element ED. For example, the first encapsulation layer PAS1 can be made of an inorganic material such as silicon nitride (SiNx), silicon oxide (SiOx), silicon oxynitride (SiON), or aluminum oxide (Al₂O₃), without being limited thereto.

The second encapsulation layer PCL can be disposed on the first encapsulation layer PAS1. For example, the second encapsulation layer PCL can be made of an organic material such as acrylic resin, epoxy resin, polyimide, polyethylene, or silicon oxycarbon (SiOC), without being limited thereto.

The third encapsulation layer PAS2 can be disposed on the second encapsulation layer PCL. For example, the third encapsulation layer PAS2 can be made of an inorganic material such as silicon nitride (SiNx), silicon oxide (SiOx), silicon oxynitride (SiON), or aluminum oxide (Al₂O₃).

As an example, a touch buffer film TBUF can be disposed on the encapsulation layer ENC. As an example, a touch sensor TS can be disposed on the touch buffer film TBUF. As an example, the touch buffer film TBUF and the touch sensor TS can be omitted depending on the design.

As the touch sensor TS is disposed on the touch buffer film TBUF, chemicals, moisture, or the like can be reduced or prevented from penetrating into the light emitting layer EL containing an organic material during a manufacturing process of the touch sensor TS. Accordingly, the touch buffer film TBUF can reduce or prevent damage to the light emitting layer EL, which is vulnerable to the chemicals or the moisture. For example, the touch buffer film TBUF can be made of an acrylic-based, epoxy-based, or siloxan-based organic material or an inorganic material such as silicon nitride (SiNx), without being limited thereto.

The touch sensor TS can include touch sensor metals TSM and a bridge metal BRG located in different layers. A first touch interlayer insulating film TILD1 can be disposed between the touch sensor metals TSM and the bridge metal BRG. Each of the touch sensor metals TSM and the bridge metal BRG can be formed of a single layer or multiple layers of conductive materials (e.g., metal materials).

When the touch sensor metals TSM need to be electrically connected to each other, the touch sensor metals TSM can be electrically connected to each other via the bridge metal BRG. The bridge metal BRG can be insulated from the touch sensor metals TSM by the first touch interlayer insulating film TILD1. The first touch interlayer insulating film TILD1 can be made of an inorganic material, for example, silicon nitride (SiNx), without being limited thereto. The first touch interlayer insulating film TILD1 can have a refractive index in a range from 1.9 to 1.92 when measured at a room temperature, without being limited thereto. As an example, the first touch interlayer insulating film TILD1 can be made of an inorganic material other than silicon nitride (SiNx). As an example, the first touch interlayer insulating film TILD1 can be made of silicon oxide (SiOx), silicon nitric oxide (SiOxNy), etc. As an example, the first touch interlayer insulating film TILD1 can have a refractive index lower than 1.9 or higher than 1.92.

A protective layer PAC can be disposed on the first touch interlayer insulating film TILD1 while covering the touch sensor TS. For example, the protective layer PAC can be made of an organic material, without being limited thereto.

Referring to FIG. 3, a stacked structure of the transmissive area TA included in the low-resolution area LA will be described now.

Other than an insulating material contained in the first pixel area PA1, the metal material layers BSM, GATE, GM, TM, SD1, and SD2 related to the sub-pixel circuit and the semiconductor layer ACT may not be disposed in the transmissive area TA of the low-resolution area LA.

Additionally, the anode electrode AE and the cathode electrode CE included in the light emitting element ED may not be disposed in the transmissive area TA of the low-resolution area LA. However, the light emitting layer EL can be disposed in the transmissive area TA of the low-resolution area LA. As an example, at least one common layer among several layers constituting the light emitting layer EL can be disposed in the transmission area TA of the low resolution area LA. Embodiments are not limited thereto. As an example, the light emitting layer EL can be not disposed in the transmissive area TA.

The transmissive area TA of the low-resolution area LA can correspond to an opening of the cathode electrode CE. The transmissive area TA of the low-resolution area LA can overlap the opening of the cathode electrode CE. As an example, the transmissive area TA of the low-resolution area LA can have the same size as the opening of the cathode electrode CE, or can have a size greater or smaller than the opening of the cathode electrode CE.

An anti-deposition film MPL that can reduce or prevent deposition of the cathode electrode CE when forming the cathode electrode CE can be disposed in the transmissive area TA of the low-resolution area LA. As an example, the transmissive area TA of the low-resolution area LA can correspond to the anti-deposition film MPL. As an example, the transmissive area TA of the low-resolution area LA can have the same size as the anti-deposition film MPL, or can have a size greater or smaller than the anti-deposition film MPL. As an example, the anti-deposition film MPL can be more transparent than the cathode electrode CE, without being limited thereto. As an example, the anti-deposition film MPL can be omitted depending on the design. The anti-deposition film MPL can be previously disposed only on the transmissive area TA of the low-resolution area LA using a fine metal mask before depositing the cathode electrode CE. The anti-deposition film MPL can be disposed on the light emitting layer EL or a common layer of the light emitting layer EL. The anti-deposition film MPL can be formed of an organic material.

Additionally, the touch sensor metal TSM and the bridge metal BRG included in the touch sensor TS may not be disposed in the transmissive area TA of the low-resolution area LA. The touch sensor TS can be configured as a mesh type. The touch sensor metal TSM of the touch sensor TS can be configured as a mesh type.

As the metal material layer, the semiconductor layer, the electrode material layer, and the like are not disposed in the transmissive area TA of the low-resolution area LA, a high light transmittance, especially, a high transmittance of infrared light of a first wavelength (e.g., a 940 nm wavelength) of the transmissive area TA of the low-resolution area LA can be provided.

Therefore, an infrared sensor (or an infrared camera) 20 disposed under the low-resolution area LA can receive infrared light of the first wavelength (e.g., the 940 nm wavelength) that has passed through the transmissive area TA of the low-resolution area LA of the display panel 110 to create a high-resolution image (e.g., a high-resolution facial image).

A number of insulating films included in the first pixel area PA1 of the low-resolution area LA can also be disposed in the transmissive area TA of the low-resolution area LA. As an example, the buffer layers MBUF and ABUF between the substrate SUB1 and SUB2 and the thin film transistor TFT, the gate insulating film GI between the semiconductor layer ACT and the gate electrode GATE, the interlayer insulating films ILD1 and ILD2 covering the thin film transistor TFT, the passivation layer PAS0 and the planarization layer PLN between the thin film transistor TFT and the light emitting element ED, the encapsulation layer ENC on the light emitting element ED, the touch buffer film TBUF on the encapsulation layer ENC, the first touch interlayer insulating film TILD1 on the touch buffer film TBUF, and the protective layer PAC can also be disposed in the transmissive area TA of the low-resolution area LA, without being limited thereto. As an example, at least one of the above-mentioned layers can be not disposed in the transmissive area TA of the low-resolution area LA.

The bank BANK included in the first pixel area PA1 of the low-resolution area LA may not be disposed in the transmissive area TA of the low-resolution area LA. Accordingly, in the transmissive area TA of the low-resolution area LA, the light emitting layer EL or the at least one common layer of the light emitting layer EL can be disposed on the planarization layer PLN.

For accurate facial recognition, in addition to securing the high transmittance of infrared light of the first wavelength (e.g., the 940 nm wavelength) in the transmissive area TA of the low-resolution area LA, there should be no problems when the display panel 110 is exposed to sunlight for a long time or during UV reliability evaluation that is performed by assuming such situation.

Because the cathode electrode CE is removed from the transmissive area TA of the low-resolution area LA to ensure the high transmittance of infrared light of the first wavelength, an ultraviolet light transmittance is higher than in other areas.

During the UV reliability evaluation, ultraviolet light introduced via the transmissive area TA of the low-resolution area LA causes outgassing from the organic films under the cathode electrode CE, which causes shrinkage of the pixels and a color difference or a luminance decrease of the display panel.

In the display device 100 according to one example embodiment of the present disclosure, the bank BANK is removed from the transmissive area TA of the low-resolution area LA, thereby reducing the shrinkage of the pixels caused by the outgassing of the organic film.

However, a reliability problem still remains because of lifting of the anti-deposition film MPL in the transmissive area TA of the low-resolution area LA. Therefore, another solution to lower the ultraviolet light transmittance while increasing the infrared light transmittance in the transmissive area TA of the low-resolution area LA is needed.

A second touch interlayer insulating film TILD2 can be further disposed on the first touch interlayer insulating film TILD1 in the transmissive area TA of the low-resolution area LA of the display device 100 according to one example embodiment of the present disclosure. The protective layer PAC can be disposed on the second touch interlayer insulating film TILD2 while covering the touch sensor TS.

As an example, the second touch interlayer insulating film TILD2 can be made of an inorganic material, for example, silicon nitride (SiNx), without being limited thereto. The second touch interlayer insulating film TILD2 and the first touch interlayer insulating film TILD1 can be made of silicon nitride (SiNx) of the same composition. Silicon to nitrogen content ratios of the second touch interlayer insulating film TILD2 and the first touch interlayer insulating film TILD1 can be the same, without being limited thereto. The second touch interlayer insulating film TILD2 and the first touch interlayer insulating film TILD1 can have the same refractive index. For example, the second touch interlayer insulating film TILD2 and the first touch interlayer insulating film TILD1 can have a refractive index in a range from 1.9 to 1.92, without being limited thereto. As an example, the second touch interlayer insulating film TILD2 and the first touch interlayer insulating film TILD1 can have a refractive index lower than 1.9 or higher than 1.92.A thickness of the second touch interlayer insulating film TILD2 can be greater than a thickness of the first touch interlayer insulating film TILD1. The thickness of the second touch interlayer insulating film TILD2 can be, for example, in a range from 3000 Å to 5000 Å, and preferably 4000 Å. The thickness of the first touch interlayer insulating film TILD1 may, for example, in a range from 1500 Å to 2500 Å, and preferably 2000 Å. Embodiments are not limited thereto. As an example, the thickness of the second touch interlayer insulating film TILD2 can be equal to or smaller than a thickness of the first touch interlayer insulating film TILD1. As an example, thickness of the second touch interlayer insulating film TILD2 can be smaller than 3000 Å, or can be greater than 5000 Å.

Alternately, in one example embodiment, the second touch interlayer insulating film TILD2 can be made of silicon nitride (SiNx) with a nitrogen content lower than that of the first touch interlayer insulating film TILD1. As an example, the second touch interlayer insulating film TILD2 can have a greater refractive index than the first touch interlayer insulating film TILD1. As an example, as long as the second touch interlayer insulating film TILD2 has a refractive index greater than or equal to that of the first touch interlayer insulating film TILD1, the second touch interlayer insulating film TILD2 can be made of any material other than silicon nitride (SiNx). In this case, the thickness of the second touch interlayer insulating film TILD2 can be greater than, equal to or smaller than a thickness of the first touch interlayer insulating film TILD1.

As such, as the second touch interlayer insulating film TILD2 is additionally disposed on the first touch interlayer insulating film TILD1, the ultraviolet light transmittance of the transmissive area TA of the low-resolution area LA can be reduced.

Therefore, according to one example embodiment of the present disclosure, the shrinkage of the pixels caused by the outgassing of the organic film in the low-resolution area LA can be reduced or prevented, and the lifting of the anti-deposition film MPL in the transmissive area TA of the low-resolution area LA can be reduced or prevented. Although it is described or illustrated that the second touch interlayer insulating film TILD2 is disposed on the first touch interlayer insulating film TILD1, the embodiments are not limited thereto. As an example, the second touch interlayer insulating film TILD2 can be disposed on any layer above the cathode electrode CE and below the protective layer PAC. As an example, the second touch interlayer insulating film TILD2 can be disposed on the cathode electrode CE, the encapsulation layer ENC, etc.

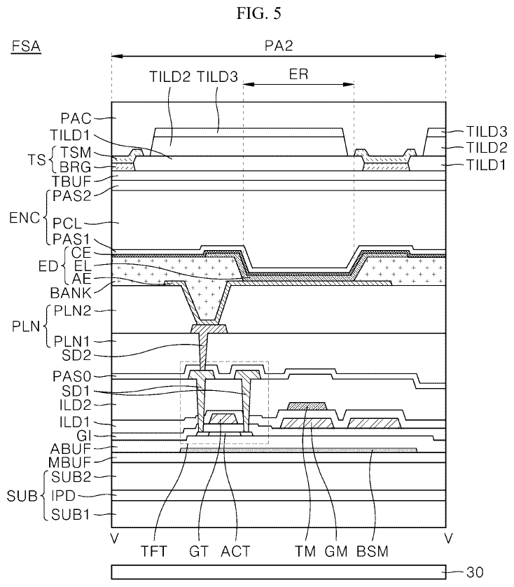

FIG. 4 is a plan view showing a fingerprint recognition area of a display device according to an example embodiment of the present disclosure. FIG. 5 is a cross-sectional view taken along a line V-V in FIG. 4.

Referring to FIG. 4, a plurality of second pixel areas PA2 can be repeatedly arranged in the fingerprint recognition area FSA. Unlike the low-resolution area LA, the fingerprint recognition area FSA may not include the transmissive areas.

Referring to FIG. 5, a stacked structure of the fingerprint recognition area FSA will be described.

The second pixel area PA2 of the fingerprint recognition area FSA can have a stacked structure similar to that of the first pixel area PA1 of the low-resolution area LA. However, unlike the stacked structure of the first pixel area PA1 of the low-resolution area LA, the second touch interlayer insulating film TILD2 and a third touch interlayer insulating film TILD3 can be additionally disposed on the first touch interlayer insulating film TILD1 in the fingerprint recognition area FSA. The protective layer PAC can be disposed on the third touch interlayer insulating film TILD3 while covering the touch sensor TS. A stacked structure located under the touch sensor TS of the fingerprint recognition area FSA can be the same as the stacked structure of the first pixel area PA1 of the low-resolution area LA, without being limited thereto.

The second touch interlayer insulating film TILD2 can be made of silicon nitride (SiNx). The second touch interlayer insulating film TILD2 and the first touch interlayer insulating film TILD1 can be made of silicon nitride (SiNx) of the same composition. The silicon to nitrogen content ratios of the second touch interlayer insulating film TILD2 and the first touch interlayer insulating film TILD1 can be the same. The second touch interlayer insulating film TILD2 and the first touch interlayer insulating film TILD1 can have the same refractive index. For example, the second touch interlayer insulating film TILD2 and the first touch interlayer insulating film TILD1 can have the refractive index in the range from 1.9 to 1.92, without being limited thereto. The thickness of the second touch interlayer insulating film TILD2 can be greater than the thickness of the first touch interlayer insulating film TILD1, without being limited thereto. The thickness of the second touch interlayer insulating film TILD2 can be, for example, in the range from 3000 Å to 5000 Å, and preferably 4000 Å, without being limited thereto. The thickness of the first touch interlayer insulating film TILD1 can be, for example, in the range from 1500 Å to 2500 Å, and preferably 2000 Å, without being limited thereto.

Alternately, in one example embodiment, the second touch interlayer insulating film TILD2 can be made of silicon nitride (SiNx) with the lower nitrogen content than the first touch interlayer insulating film TILD1. As an example, the second touch interlayer insulating film TILD2 can have the greater refractive index than the first touch interlayer insulating film TILD1.

As an example, the third touch interlayer insulating film TILD3 can be made of silicon nitride (SiNx), without being limited thereto. As an example, the third touch interlayer insulating film TILD3 can be made of silicon nitride (SiNx) with a different composition from that of the first and second touch interlayer insulating films TILD1 and TILD2. A silicon to nitrogen content ratio of the third touch interlayer insulating film TILD3 can be different from the silicon to nitrogen content ratio of the first and second touch interlayer insulating films TILD1 and TILD2. The third touch interlayer insulating film TILD3 can be made of silicon nitride (SiNx) with a higher nitrogen content than that of the first and second touch interlayer insulating films TILD1 and TILD2. The third touch interlayer insulating film TILD3 can have a smaller refractive index than the second touch interlayer insulating film TILD2. For example, the third touch interlayer insulating film TILD3 can have a refractive index in a range from 1.8 to 1.82, without being limited thereto. As an example, the third touch interlayer insulating film TILD3 can have a refractive index lower than 1.8 or higher than 1.82. As an example, as long as the third touch interlayer insulating film TILD3 has a smaller refractive index than the second touch interlayer insulating film TILD2, the third touch interlayer insulating film TILD3 can be made of any material other than silicon nitride (SiNx). A thickness of the third touch interlayer insulating film TILD3 can be smaller than the thickness of the first touch interlayer insulating film TILD1, without being limited thereto. The thickness of the third touch interlayer insulating film TILD3 can be, for example, in a range from 500 Å to 1500 Å, and preferably 1000 Å, without being limited thereto. As an example, the thickness of the third touch interlayer insulating film TILD3 can be smaller than the thickness of the second touch interlayer insulating film TILD2. As an example, the thickness of the third touch interlayer insulating film TILD3 can be smaller than 500 Å or can be greater than 1500 Å. As an example, the thickness of the third touch interlayer insulating film TILD3 can be equal to or greater than the thickness of the first touch interlayer insulating film TILD1.

Because an image for sensing a user's fingerprint does not require high definition like an image for the facial recognition, the separate transmissive areas are not disposed in the fingerprint recognition area FSA. Embodiments are not limited thereto. As an example, the separate transmissive areas can be further disposed in the fingerprint recognition area FSA.

Since there are no transmissive areas in the fingerprint recognition area FSA, using infrared light of a second wavelength (e.g., 1300 nm) that is longer than the first wavelength of infrared light used for the face recognition in the low-resolution area LA can be advantageous for a fingerprint sensor 30 disposed under the fingerprint recognition area FSA to recognize the user's fingerprint. Embodiments are not limited thereto. As an example, the fingerprint sensor 30 can use an infrared light of a wavelength equal to the first wavelength of infrared light used for the face recognition in the low-resolution area LA, or the fingerprint sensor 30 may not use an infrared light.

As such, as the third touch interlayer insulating film TILD3, which has the lower refractive index, is additionally disposed on the second touch interlayer insulating film TILD2, the transmittance of infrared light of the second wavelength (e.g., 1300 nm) in the fingerprint recognition area FSA can be improved.

Therefore, according to one example embodiment of the present disclosure, a rate of the user's fingerprint recognition by the fingerprint sensor 30 can be increased and a fingerprint recognition error can be reduced or prevented in the fingerprint recognition area FSA.

FIG. 6 is a plan view showing a normal area of a display device according to an example embodiment of the present disclosure.

Referring to FIG. 6, a stacked structure of the normal area NA will be described. Similar to the fingerprint recognition area FSA, a plurality of third pixel areas PA3 can be repeatedly arranged in the normal area NA without the transmissive areas.

The third pixel area PA3 of the normal area NA can have the same stacked structure as the first pixel area PA1 of the low-resolution area LA.

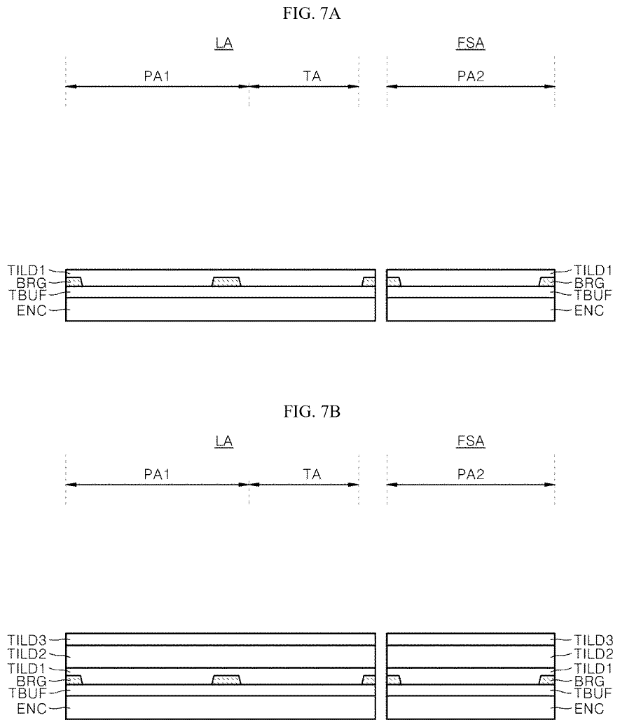

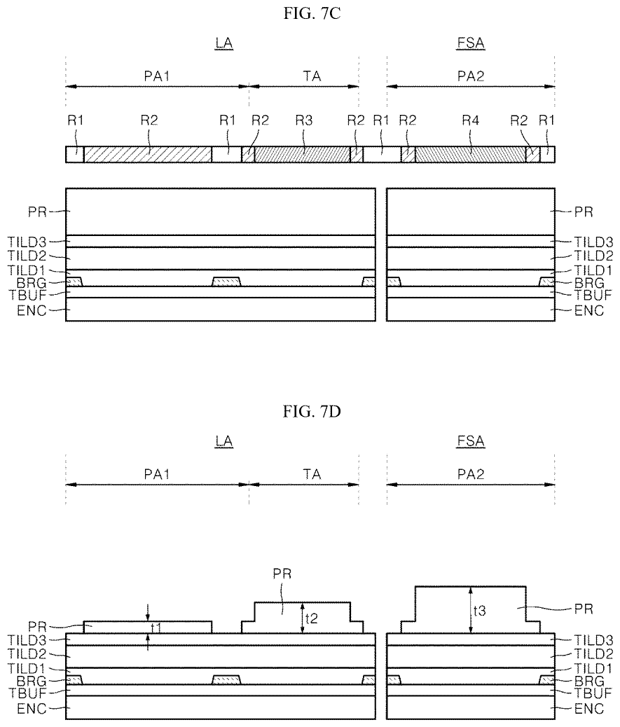

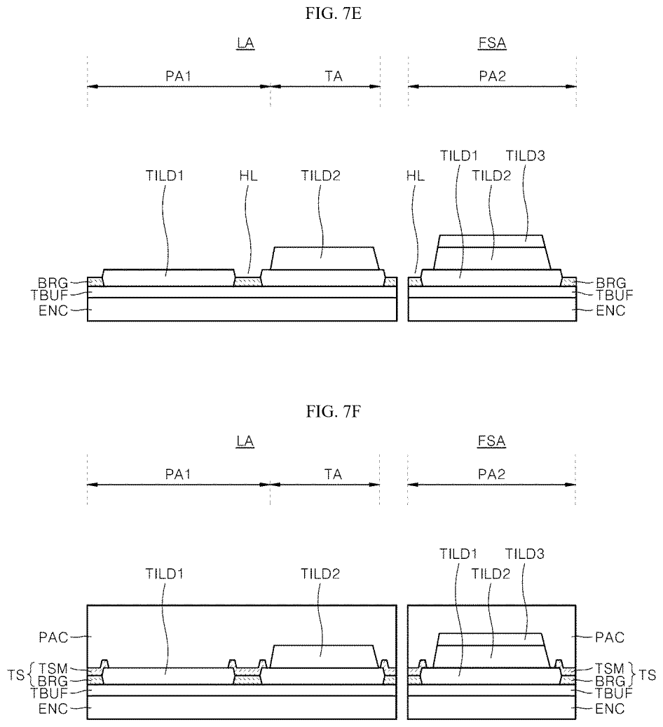

FIGS. 7A to 7F are cross-sectional views showing a method for manufacturing a display device according to an example embodiment of the present disclosure.

Referring to FIG. 7A, the thin film transistor, the light emitting element, and the like are formed in the low-resolution area LA and the fingerprint recognition area FSA, and then the encapsulation layer ENC is formed.

Then, the touch buffer film TBUF is formed on the encapsulation layer ENC and the bridge metal BRG or the touch sensor metal TSM is formed on the touch buffer film TBUF.

Then, the first touch interlayer insulating film TILD1 covering the bridge metal BRG is formed.

Referring to FIG. 7B, the second touch interlayer insulating film TILD2 and the third touch interlayer insulating film TILD3 are sequentially formed on the first touch interlayer insulating film TILD1.

In both the low-resolution area LA and the fingerprint recognition area FSA, the first touch interlayer insulating film TILD1, the second touch interlayer insulating film TILD2, and the third touch interlayer insulating film TILD3 are stacked on a top surface of the encapsulation layer ENC.

Referring to FIG. 7C, photoresist PR is applied on the third touch interlayer insulating film TILD3 in the low-resolution area LA and the fingerprint recognition area FSA, and then a photolithography process is performed using a half tone mask.

The half tone mask includes areas with various light transmittances. For example, a first area R1 can be an area with the highest light transmittance and a fourth area R4 can be an area with the lowest light transmittance. A second area R2 can have lower light transmittance than the first area R1, but can have higher light transmittance than a third area R3.

The first area R1 can overlap an area where a hole exposing the bridge metal BRG will be formed, the second area R2 can overlap an area where the first touch interlayer insulating film TILD1 will remain, the third area R3 can overlap an area where the second touch interlayer insulating film TILD2 will remain, and the fourth area R4 can overlap an area where the third touch interlayer insulating film TILD3 will remain.

Referring to FIG. 7D, the photoresist PR with a first thickness t1 remains in the first pixel area PA1 of the low-resolution area LA, except for some areas located on the bridge metal BRG.

In the transmissive area TA of the low-resolution area LA, the photoresist PR with the first thickness t1 remains in some areas and the photoresist PR with a second thickness t2 remains in the remaining area. Also, in the transmissive area TA of the low-resolution area LA, the photoresist PR may not remain on the bridge metal BRG. The second thickness t2 is greater than the first thickness t1.

In the fingerprint recognition area FSA, the photoresist PR with the first thickness t1 remains in some areas and the photoresist PR with a third thickness t3 remains in the remaining area. Also in the fingerprint recognition area FSA, the photoresist PR may not remain on the bridge metal BRG. The third thickness t3 is greater than the second thickness t2.

Referring to FIG. 7E, an etching process is performed using the photoresist PR remaining in the first pixel area PA1 and the transmissive area TA of the low-resolution area LA, and the fingerprint recognition area FSA as an etching mask.

As a result, holes HL exposing the bridge metal BRG or touch sensor metal TSM in the first pixel area PA1 and the transmissive area TA of the low-resolution area LA and the fingerprint recognition area FSA are formed in the first touch interlayer insulating film TILD1. The first touch interlayer insulating film TILD1 remains in the first pixel area PA1 of the low-resolution area LA. The first touch interlayer insulating film TILD1 and the second touch interlayer insulating film TILD2 remain in the transmissive area TA of the low-resolution area LA. In addition, the first touch interlayer insulating film TILD1, the second touch interlayer insulating film TILD2, and the third touch interlayer insulating film TILD3 remain in the fingerprint recognition area FSA. Although it is described and illustrated that the holes HL, the first touch interlayer insulating film TILD1, the second touch interlayer insulating film TILD2 and the third touch interlayer insulating film TILD3 are formed in the same etching process, by using a half tone mask, the embodiments are not limited thereto. As an example, at least one of the holes HL, the first touch interlayer insulating film TILD1, the second touch interlayer insulating film TILD2 and the third touch interlayer insulating film TILD3 can be formed in a separate process, for example, without a half tone mask.

Referring to FIG. 7F, the touch sensor metals TSM connected to the bridge metal BRG are formed in the holes HL, or the bridge metal BRG TSM connected to the touch sensor metals is formed in the holes HL. The touch sensor metals TSM can be further formed on a top surface of the first touch interlayer insulating film TILD1. In addition, the protective layer PAC can be disposed on the first to third touch interlayer insulating films TILD1, TILD2, and TILD3 while covering the touch sensor TS.

A display panel and a display device according to example embodiments of the present disclosure can be described as follows.

A display panel according to an example embodiment of the present disclosure includes a first area including a plurality of first pixel areas and a plurality of transmissive areas, wherein a light emitting element is disposed in each first pixel area and each transmissive area overlaps an opening of a cathode electrode of the light emitting element, a second area including a plurality of second pixel areas and having a higher pixel density than the first area, a touch sensor disposed in the first area and the second area and including a touch sensor metal and a bridge metal located in different layers, a first touch interlayer insulating film disposed between the touch sensor metal and the bridge metal in the first area and the second area, and a second touch interlayer insulating film disposed on the first touch interlayer insulating film in the plurality of transmissive areas of the first area and in the second area.

According to an example embodiment of the present disclosure, the first touch interlayer insulating film and the second touch interlayer insulating film can be made of silicon nitride.

According to an example embodiment of the present disclosure, a silicon to nitrogen content ratio of the second touch interlayer insulating film can be the same as a silicon to nitrogen content ratio of the first touch interlayer insulating film.

According to an example embodiment of the present disclosure, a thickness of the second touch interlayer insulating film can be greater than a thickness of the first touch interlayer insulating film.

According to an example embodiment of the present disclosure, the display panel can further include a third touch interlayer insulating film disposed on the second touch interlayer insulating film in the second area.

According to an example embodiment of the present disclosure, the third touch interlayer insulating film can be made of silicon nitride.

According to an example embodiment of the present disclosure, a silicon to nitrogen content ratio of the third touch interlayer insulating film can be different from a silicon to nitrogen content ratio of the second touch interlayer insulating film.

According to an example embodiment of the present disclosure, a nitrogen content of the third touch interlayer insulating film can be greater than a nitrogen content of the second touch interlayer insulating film.

According to an example embodiment of the present disclosure, a refractive index of the third touch interlayer insulating film can be smaller than a refractive index of the second touch interlayer insulating film.

According to an example embodiment of the present disclosure, a thickness of the third touch interlayer insulating film can be smaller than a thickness of the second touch interlayer insulating film.

A display device according to an example embodiment of the present disclosure includes a display panel including a display area and a non-display area, wherein the display area includes a first area including a plurality of first pixel areas and a plurality of transmissive areas, and a second area including a plurality of second pixel areas and having a higher pixel density than the first area, wherein a light emitting element is disposed in each first pixel area, wherein each transmissive area overlaps an opening of a cathode electrode of the light emitting element, an infrared sensor overlapping the first area and located on a rear surface of the display panel, and a fingerprint sensor overlapping the second area and located on the rear surface of the display panel, and the display panel includes a touch sensor disposed in the first area and the second area and including a touch sensor metal and a bridge metal located in different layers, a first touch interlayer insulating film disposed between the touch sensor metal and the bridge metal in the first area and the second area, and a second touch interlayer insulating film disposed on the first touch interlayer insulating film in the plurality of transmissive areas of the first area and the second area.

According to an example embodiment of the present disclosure, the first touch interlayer insulating film and the second touch interlayer insulating film can be made of silicon nitride.

According to an example embodiment of the present disclosure, a silicon to nitrogen content ratio of the second touch interlayer insulating film can be the same as a silicon to nitrogen content ratio of the first touch interlayer insulating film.

According to an example embodiment of the present disclosure, a thickness of the second touch interlayer insulating film can be greater than a thickness of the first touch interlayer insulating film.

According to an example embodiment of the present disclosure, the display device can further include a third touch interlayer insulating film disposed on the second touch interlayer insulating film in the second area.

According to an example embodiment of the present disclosure, the third touch interlayer insulating film can be made of silicon nitride.

According to an example embodiment of the present disclosure, a silicon to nitrogen content ratio of the third touch interlayer insulating film can be different from a silicon to nitrogen content ratio of the second touch interlayer insulating film.

According to an example embodiment of the present disclosure, a nitrogen content of the third touch interlayer insulating film can be greater than a nitrogen content of the second touch interlayer insulating film.

According to an example embodiment of the present disclosure, a refractive index of the third touch interlayer insulating film can be smaller than a refractive index of the second touch interlayer insulating film.

According to an example embodiment of the present disclosure, a thickness of the third touch interlayer insulating film can be smaller than a thickness of the second touch interlayer insulating film.

As described above, the present disclosure is described with reference to illustrative drawings, but the present disclosure is not limited by the embodiments and drawings disclosed in the present disclosure.

It is obvious that various modifications can be made by a person skilled in the art within the scope of the technical idea of the present disclosure.

In addition, even when the effects of the configuration of an embodiment of the present disclosure were not explicitly described and explained earlier while describing an embodiment of the present disclosure, it is natural that the predictable effects of the configuration should also be recognized. Although the embodiments of the present disclosure have been described in more detail with reference to the accompanying drawings, the present disclosure is not necessarily limited to these embodiments, and can be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

What is claimed is:

1. A display panel comprising:
a first area including a plurality of first pixel areas and a plurality of transmissive areas, each first pixel area having a light emitting element disposed therein;
a second area including a plurality of second pixel areas but no transmissive area;
a touch sensor disposed in the first area and the second area and including a plurality of first openings in the first area; and
an organic layer formed on a same layer as a cathode electrode of the light emitting element in the first area and overlapping the plurality of first openings.

2. The display panel of claim 1, wherein each transmissive area overlaps an opening of the cathode electrode of the light emitting element in the first area, and
wherein the organic layer is formed in the opening of the cathode electrode of the light emitting element in the first area.

3. The display panel of claim 1, wherein the touch sensor is configured as a mesh type, and further comprises a plurality of second openings in the first area and the second area.

4. The display panel of claim 3, wherein each of the plurality of second openings is positioned to correspond to a light emitting area of a sub-pixel in the first area and the second area.

5. The display panel of claim 1, further comprising a thin film transistor disposed on a substrate for driving a light emitting element of a sub-pixel in the first area and the second area.

6. The display panel of claim 5, further comprising:
a first planarization layer on the thin film transistor; and
an electrode pattern disposed on the first planarization layer for electrically connecting the thin film transistor and the light emitting element.

7. The display panel of claim 6, further comprising a second planarization layer on the electrode pattern,
wherein a light emitting layer of the light emitting element is disposed on the second planarization layer in the transmissive areas.

8. The display panel of claim 7, wherein the organic layer is disposed on the light emitting layer in the transmissive areas.

9. The display panel of claim 7, wherein the light emitting layer disposed in the transmissive areas comprises an organic light emitting layer and at least one of a hole injection layer, a hole transport layer, an electron transport layer, and an electron injection layer.

10. The display panel of claim 5, further comprising a metal layer disposed on the substrate and below the thin film transistor,
wherein the metal layer includes openings overlapping the plurality of first openings.

11. The display panel of claim 1, further comprising a bank configured to define a light emitting area of each sub-pixel in the first area and the second area,
wherein the bank includes openings overlapping the plurality of transmissive areas.

12. The display panel of claim 11, wherein the bank includes an organic material containing black pigment.

13. The display panel of claim 1, further comprising:
an insulating film disposed on the cathode electrode of the light emitting element in the plurality of transmissive areas of the first area, but not disposed in the second area.

14. The display panel of claim 13, wherein the touch sensor includes a touch sensor metal and a bridge metal located in different layers,
wherein the display panel further comprises a first touch interlayer insulating film disposed between the touch sensor metal and the bridge metal in the first area and the second area, and
wherein the insulating film constitutes a second touch interlayer insulating film disposed on the first touch interlayer insulating film in the plurality of transmissive areas of the first area.

15. The display panel of claim 14, wherein the first touch interlayer insulating film and the second touch interlayer insulating film include silicon nitride.

16. The display panel of claim 15, wherein a silicon to nitrogen content ratio of the second touch interlayer insulating film is the same as a silicon to nitrogen content ratio of the first touch interlayer insulating film.

17. The display panel of claim 14, wherein a thickness of the second touch interlayer insulating film is greater than a thickness of the first touch interlayer insulating film.

18. The display panel of claim 14, further comprising:
a third area including a plurality of third pixel areas, the second touch interlayer insulating film being further disposed on the first touch interlayer insulating film in the third area; and
a third touch interlayer insulating film disposed on the second touch interlayer insulating film in the third area, but not disposed in the first area and the second area.

19. The display panel of claim 18, wherein the third touch interlayer insulating film is made of silicon nitride.

20. The display panel of claim 19, wherein a silicon to nitrogen content ratio of the third touch interlayer insulating film is different from a silicon to nitrogen content ratio of the second touch interlayer insulating film.

21. The display panel of claim 19, wherein a nitrogen content of the third touch interlayer insulating film is greater than a nitrogen content of the second touch interlayer insulating film.

22. The display panel of claim 18, wherein a refractive index of the third touch interlayer insulating film is smaller than a refractive index of the second touch interlayer insulating film.

23. The display panel of claim 18, wherein a thickness of the third touch interlayer insulating film is smaller than a thickness of the second touch interlayer insulating film.

24. The display panel of claim 18, wherein the transmissive area is not disposed in the third area.

25. The display panel of claim 18, wherein holes exposing the bridge metal or the touch sensor metal in the first touch interlayer, the second touch interlayer insulating film and the third touch interlayer insulating film are formed in a same etching process, by using a half tone mask.

26. A display device comprising:
the display panel of claim 2; and
an infrared sensor overlapping the first area and located on a rear surface of the display panel.

27. A display device comprising:
the display panel of claim 18; and
a fingerprint sensor overlapping the third area and located on the rear surface of the display panel.

28. The display device of claim 27, further comprising an infrared sensor overlapping the first area and located on the rear surface of the display panel.

29. The display device of claim 28, wherein the fingerprint sensor uses an infrared light of a second wavelength longer than a first wavelength of an infrared light used by the infrared sensor.
